(19) United States
(12) Patent Application Publication
(10) Pub. No.: US 2012/0182673 A1
(43) Pub. Date: Jul. 19, 2012

(54) PUSH-BUTTON ASSEMBLY AND ELECTRONIC DEVICE USING THE SAME

(75) Inventors: YUAN-MING WANG, Shenzhen City (CN); XUE-FENG WAN, Shenzhen City (CN); ZHAO-YONG LI, Shenzhen City (CN); CHIN-SUNG YANG, Tu-Cheng (TW)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/165,862

(22) Filed: Jun. 22, 2011

(30) Foreign Application Priority Data
Jan. 13, 2011 (CN) 201110006840.5

(51) Int. Cl. H05K 5/02; H01H 3/12

(52) U.S. Cl. 361/679.01; 200/341

(57) ABSTRACT

An electronic device includes a main body and a push-button assembly. The main body defines a first through hole. The push-button assembly is detachably connected to the main body. The main body partially protrudes out of the main body from the through hole. The push-button assembly can rotate relative to the main body along a first direction to be locked to the main body and rotate relative to the main body along a second direction opposite to the first direction to be unlocked from the main body.

### BACKGROUND

1. Technical Field

The present disclosure relates to electronic devices, and particularly to an electronic device with a push-button assembly for actuating a switch.

2. Description of Related Art

Many electronic devices often include a push-button assembly that can be pushed by users to actuate a switch disposed in the electronic devices for controlling a function of the electronic device. The push-button assembly is often mounted to a main body of the electronic device with screws or by using fusing technology. However, when users want to remove the push-button assembly from the main body that has been assembled with the above mentioned technology it can be very time consuming and inconvenient.

Therefore, there is room for improvement in the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a schematic view of an electronic device according to an embodiment of the present disclosure. The electronic device includes a main body and a push-button assembly connected to the main body.

FIG. 2 is a partial schematic view of the main body of FIG. 1, the electronic device of FIG. 1 further includes a connection structure partially shown in FIG. 2.

FIG. 3 is a schematic view of the push-button assembly of FIG. 1, also partially showing the connection structure related to FIG. 2.

FIG. 4 is similar to FIG. 3 but from a reverse angle.

FIG. 5 is a schematic view showing the engagement between the main body, the push-button assembly, and the connection structure showing in FIGS. 1-3 with the push-button assembly in a locked position.

FIG. 6 is similar to FIG. 5 with the push-button assembly in an unlocked position.

### DETAILED DESCRIPTION

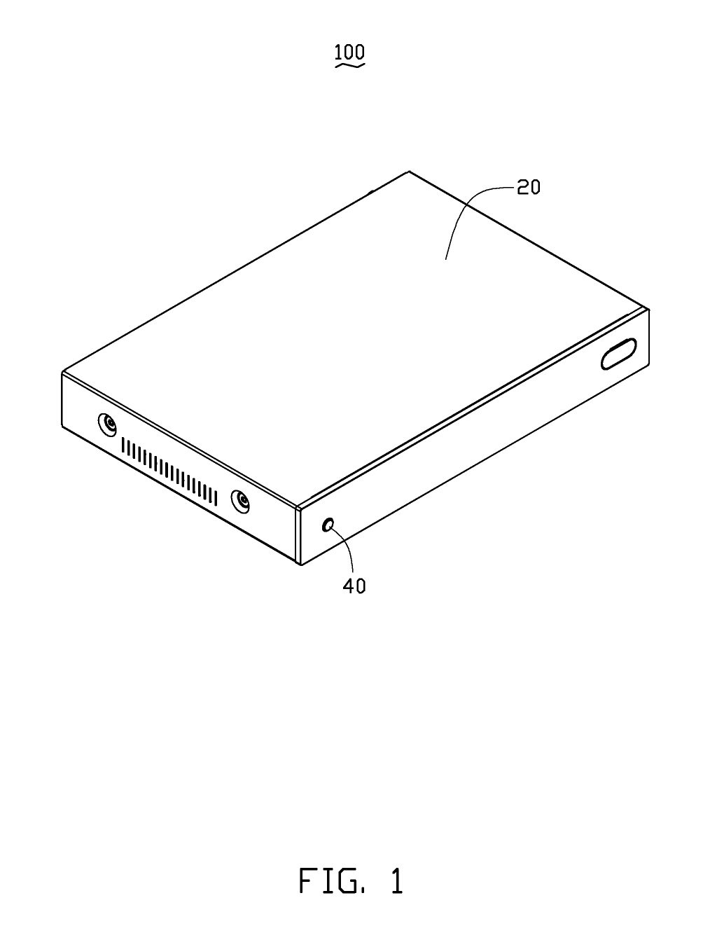

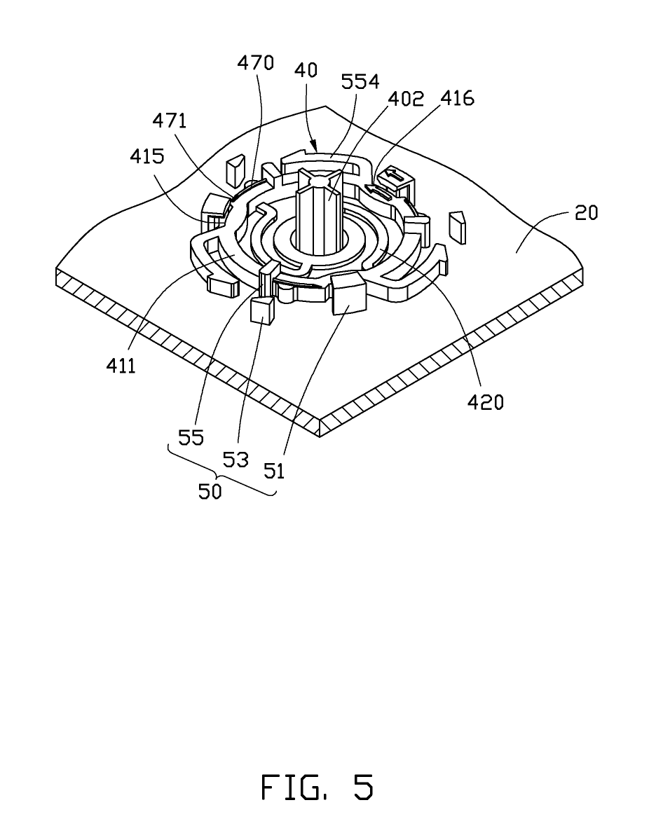

Referring to FIGS. 1, an electronic device 100 in accordance with an embodiment includes a main body 20, a push-button assembly 40 mounted to the main body 20, and a connection structure 50 as shown in FIG. 5 for connecting the push-button assembly 40 with the main body 20. The push-button assembly 40 is used for actuating a switch (not shown) in the main body 20 to implement a function of the electronic device such as operation selection, or resetting. The electronic device 100 may be any electronic device with the push-button assembly 40 such as DVD player.

The main body 20 may be a housing of the electronic device 100 and may include an exterior surface 200 and an interior surface 210 opposite to the exterior surface 200. A through hole 230 is defined in the main body 20 to communicate between the interior and the exterior of the main body 20.

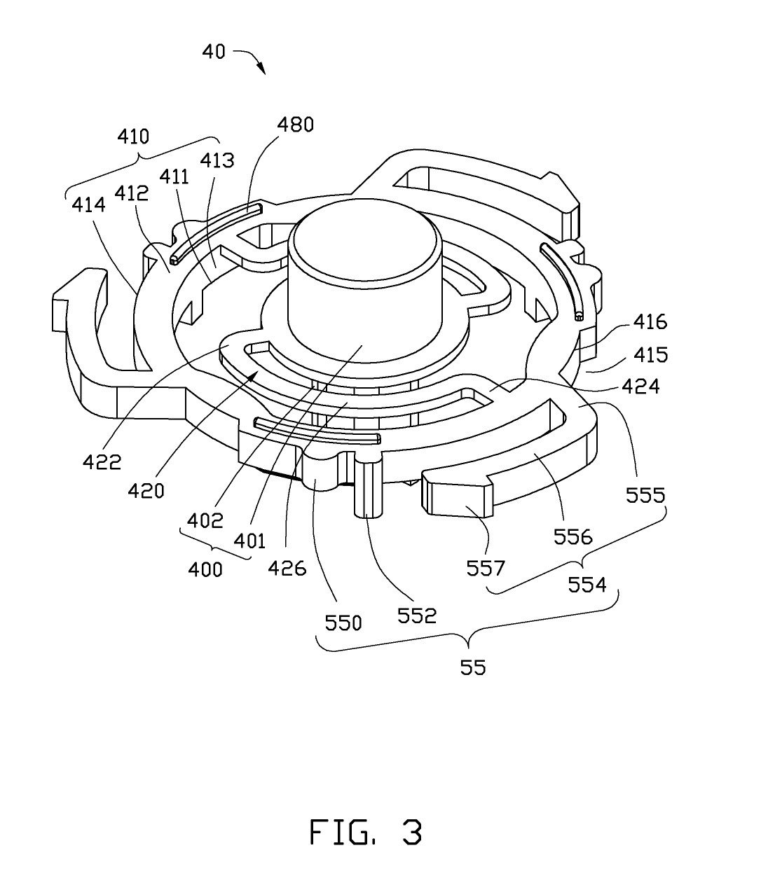

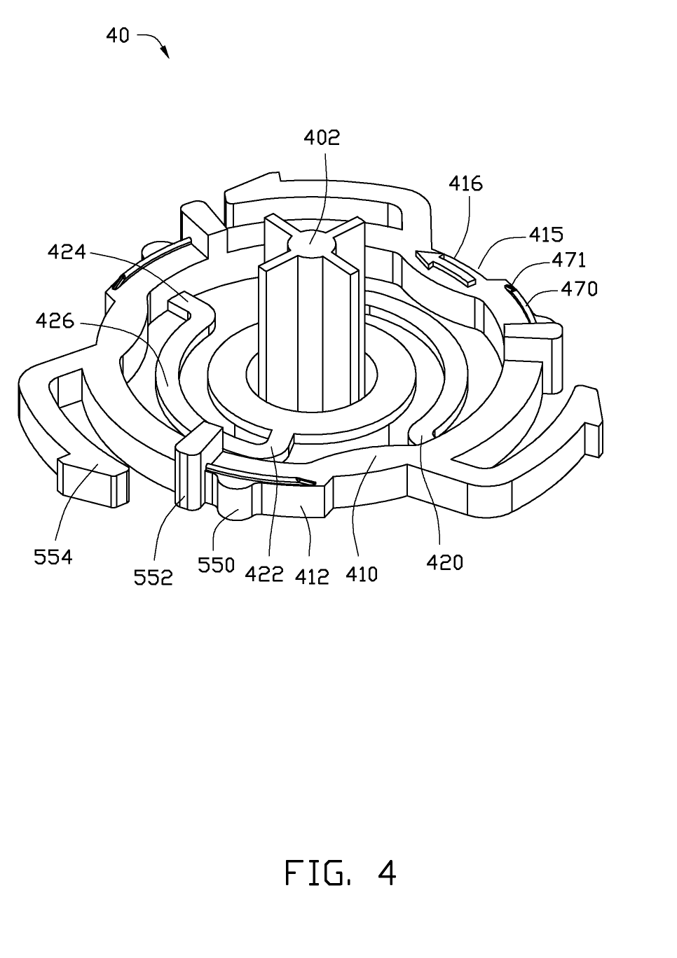

Referring to FIGS. 3-4, the push-button assembly 40 includes a push-button 400, a frame 410, two elastic arms 420, three first abutting ribs 470, and three second abutting ribs 480. The push-button 400 corresponds to the through hole 230 and includes a push portion 401 and an actuating portion 402 connected to the push portion 401. The frame 410 is annular shaped and surrounds the push-button 400. The frame 410 includes a first surface 411 substantially parallel to and away from the interior surface 210 of the main body 20. A second surface 412 opposite to the first surface 411, a third surface 413 connecting the first and second surfaces 411, 412 facing the push-button 400, and a fourth surface 414 opposite to the first surface 411. The fourth surface 414 is recessed to define three equally-spaced concavities 415. Each concavity 415 include a bottom wall 416 exposed on the fourth surface 414.

The elastic arms 420 connect the frame 410 with the push-button 400 for allowing the push-button 400 to move along a direction perpendicular to the frame 410. Each elastic arm 420 includes a first end portion 422, a second end portion 424, and a body portion 426 connecting the first end portion 422 with the second end portion 424. The first end portion 422 is connected to the push-button 400 while the second end portion 424 is connected to the third surface 413. The body portion 426 is substantially arc shaped and substantially parallel with the third surface 413.

As shown in FIG. 4, the first abutting ribs 470 are equally-spaced and arranged on the first surface 411 and are respectively adjacent to the concavities 415. Each first abutting rib 470 is arc shaped and substantially parallel with the fourth surface 414. One end of each first rib 470, which is adjacent to the corresponding concavity 415 defines a guiding portion 471. As shown in FIG. 3, the second abutting ribs 480 are equally-spaced and arranged on the second surface 412 and respectively correspond to the first abutting ribs 470.

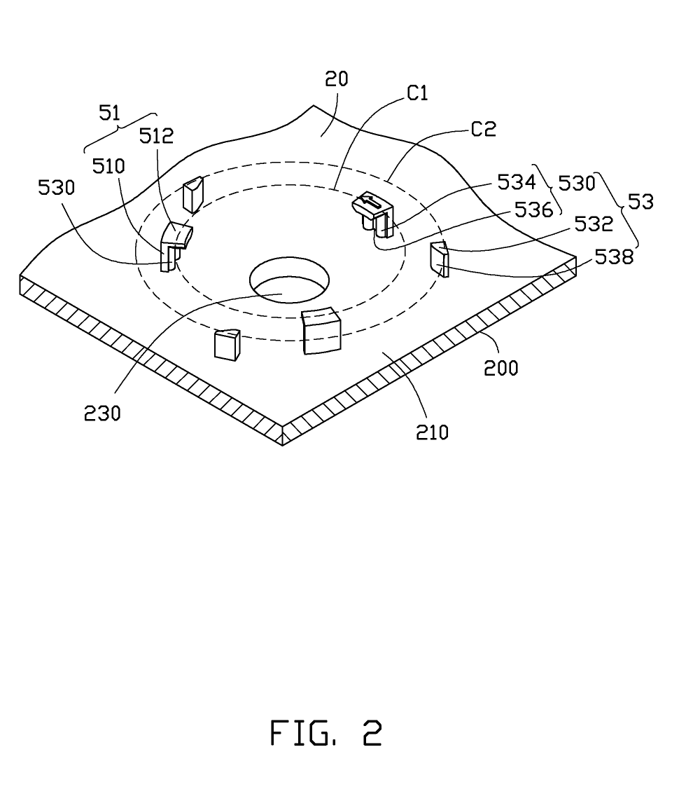

Referring to FIG. 2 again, the connection structure 50 includes three stop members 51, three first clamping members 53 and three second clamping members 55 (See FIGS. 3-4). The stop members 51 protrude from the interior surface 210 along a direction away from the interior surface 210 and face the through hole 230. Each stop member 51 is substantially L shaped, including a standing portion 510 and an extending portion 512. The standing portion 510 protrudes upwardly from the interior surface 210. The extending portion 512 perpendicularly extends from one end of the standing portion 510, which is away from the interior surface 210, towards the through hole 230. The extending portion 512 is parallel to the interior surface 210 in the embodiment. The distance between each extending portion 512 and the interior surface 210 is substantially equal to the distance between each first abutting rib 470 and the first surface 411. Also, the distance between one side of each extending portion 512, which faces towards the through hole 230 and the through hole 230 is substantially equal to the distance between each bottom wall 416 and the push-button 400.

As shown in FIG. 2, the first clamping members 53 are respectively connected to the stop members 51. Each first clamping member 53 includes a clamping portion 530 disposed on the corresponding stop member 51 and a latching portion 532 adjacent to the corresponding stop member 51. Each clamping portion 530 is disposed on a side of each standing portion 510 which faces towards the through hole 230. Each clamping portion 530 includes two clamping ribs 534 and a clamping track 536 defined between the clamping ribs 534. The three clamping portions 530 are equidistantly arranged on a first circumference C1 of a circle with the through hole 230 as center.

The latching portions 532 are equidistantly arranged on a second circumference C2 of a circle with the through hole 230 as the center. Each latching portion 532 is located between each two adjacent stop members 51. Each latching portion 532 is substantially wedge shaped, and one side, which faces towards the through hole 230 defines a guiding surface 538. In the embodiment, the radius of the circumference C2 is larger than that of C1.

As shown in FIGS. 3-4, the second clamping members 55 are connected to the frame 410. Each second clamping member 55 includes a protrusion 550, a restricting portion 552, and a hook portion 554 protruding from the fourth surface 414 and arranged in a counterclockwise order between each two adjacent concavities 415. The protrusions 550 correspond to the clamping tracks 536 (FIG. 2) respectively while the restricting portions 552 correspond to the extending portions 512 respectively.

The hook portions 554 are respectively adjacent to the concavities 415. Each hook portion 554 includes a distal end 555, a main part 556, and a hook 557. The distal end 555 protrudes from the fourth surface 414. The main part 556 extends from the end portion 555 along a direction parallel with the fourth surface 414. The hook 557 is connected to the main part 556. The distance between the main part 556 and the fourth surface 414 corresponds to the difference between the radius of C1 and C2. In the embodiment, the hook portions 554 are made of elastic material.

Referring to FIG. 5, in assembly, the push-button assembly 40 is put on the interior surface 210, and the second abutting ribs 480 contact the interior surface 210. The stop members 51 respectively correspond to the concavities 415, and the push portion 401 is inserted in the through hole 230 to be exposed on the exterior surface 200. At this time, each standing portion 510 corresponds to the corresponding bottom wall 416, the extending portion 512 does not extend above the first surface 411 of the frame 410. The push-button assembly 40 thus is in an unlocked position and can rotate in a first direction, such as counterclockwise in the embodiment and can be removed from the main body 20.

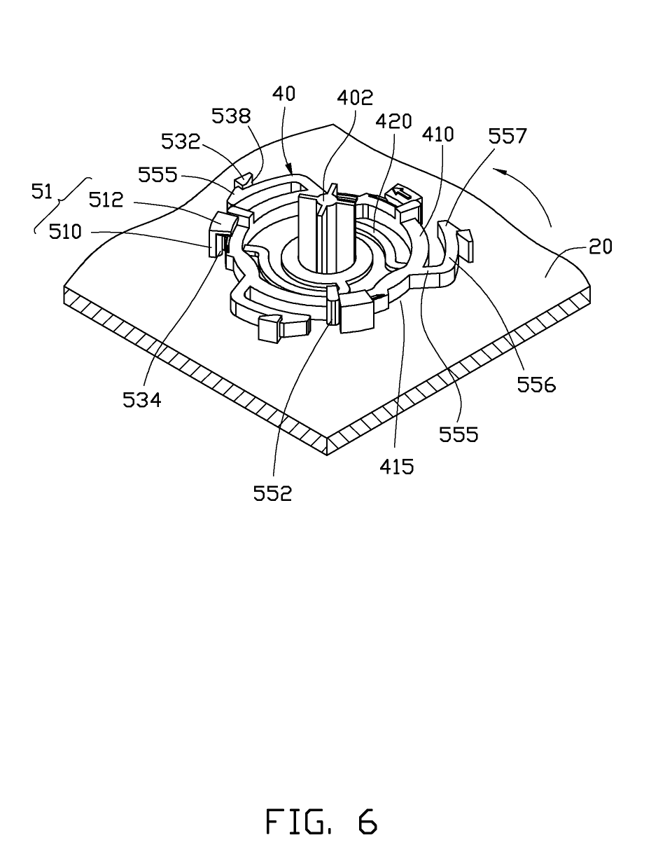

The push-button assembly 40 is rotated counterclockwise to be in a locked position, as shown in FIG. 6. As the push-button assembly 40 rotates, each first abutting rib 470 slides to under the corresponding extending portion 512 with the guidance from the guiding portion 471. At this point, the extending portions 512 respectively tightly engage with the first ribs 470 and partly extend above the first surface 411, thereby restricting the push-button assembly 40 from moving perpendicularly to the interior surface 210. The protrusions 550 are respectively received in the clamping tracks 536, therefore, the push-button assembly 40 is restricted from moving continuously counterclockwise or clockwise. Each restricting portion 552 abuts one side of the corresponding stop member 51. The push-button assembly 40, thus can no longer rotate counterclockwise. Each hook 557 also moves to hook on the corresponding latching portion 532 by the guidance of the guiding surface 538, thereby restricting the push-button assembly 40 from rotating clockwise, that is, from rotating opposite to the first direction.

In use, users can push the push portion 401 to make the push portion 401 move in the through hole 230 to drive the actuating portion 402 to actuate a circuit (not labeled) locating under the actuating portion 402. During the process, the elastic arms 420 are deformed to store elastic force. After the circuit is actuated, users can stop pushing the push portion 401, therefore, the push portion 401 turns back to its original position under the elastic force from the elastic arms 420.

In disassembly, the hooks 557 are pushed to be deformed and move towards the fourth surface 414. Meanwhile, the frame 410 is rotated clockwise to relieve the engagement between each hook 557 and the corresponding latching portion 532. As the frame 410 rotates, the protrusions 550 are respectively driven to slide out of the clamping tracks 536 to move away from the clamping portions 530. The concavities 415 move to respectively correspond to the stop members 51 again, therefore, the extending portions 512 no longer extend above the first surface 411. That is, the push-button assembly 40 is in the unlocked position again. The push-button assembly 40 can be removed from the main body 20 at this time.

The second abutting ribs 480, the contacting area between the second surface 412 and the interior surface 210 is decreased, therefore, the friction between the push-button assembly 40 and the main body 20 can be somehow decreased, making the push-button assembly 40 easily rotate on the interior surface 210.

With the engagement between the first clamping member 51 and the second clamping member 55, the push-button assembly 40 can be stably locked to the main body 20. With the conformation between the stop members 51 and the concavities 415, the push-button assembly 40 can be unlocked from the main body 20 easily. In addition, the push-button assembly 40 can be mounted to the main body 20 more stably and easily with the first abutting ribs 470 and the second abutting ribs 480.

It is to be understood, however, that even though information and advantages of the present embodiments have been set forth in the foregoing description, together with details of the structures and functions of the present embodiments, the disclosure is illustrative only; and that changes may be made in detail, especially in matters of shape, size, and arrangement of parts within the principles of the present embodiments to the full extent indicated by the broad general meaning of the terms in which the appended claims are expressed.

What is claimed is:

1. An electronic device, comprising:
a main body defining a first through hole;
a push-button assembly detachably connected to the main body and partially protruding out of the main body from the through hole;
wherein the push-button assembly can rotate relative to the main body along a first direction to be locked to the main body and rotate relative to the main body along a second direction opposite to the first direction to be unlocked from the main body.

2. The electronic device as claimed in claim 1, wherein the electronic device further comprises a connection structure for locking the push-button assembly to the main body.

3. The electronic device as claimed in claim 2, wherein the push-button assembly comprises a push-button movably disposed in the first through hole and protruding out of the main body through the first through hole, and a frame adapted to hold the push-button, the frame is retained to the main body via the connection structure.

4. The electronic device as claimed in claim 3, wherein the connection structure comprises at least one stop member protruding from an interior surface of the main body and facing towards the through hole, the at least one stop member partly covers the frame to restrict the push-button assembly from moving along a third direction substantially perpendicular to the interior surface.

5. The electronic device as claimed in claim 4, wherein each stop member comprises a standing portion protruding from the interior surface and an extending portion extending from one end of the standing portion which is away from the interior surface and facing towards the through hole.

6. The electronic device as claimed in claim 4, wherein the connection structure further comprises at least one first clamping member connected to the interior surface and at least one second clamping member disposed on the frame, the at least one first clamping member engages with the at least one second clamping member for restricting the push-button assembly from rotating relative to the main body along the first direction and the second direction.

7. The electronic device as claimed in claim 6, wherein each first clamping member comprises a clamping portion disposed on one side of each stop member and facing towards the through hole, the clamping portion defines a clamping track, the second clamping member comprises a protrusion protruding from the frame and facing away from the through hole, the protrusion is clamped in the clamping track.

8. The electronic device as claim in claim 6, wherein each second clamping member comprises a restricting portion protruding from the frame facing away from the through hole, the restricting portion abuts the at least one stop member for restricting the push-button assembly from rotating relative to the main body along the first direction.

9. The electronic device as claimed in claim 8, wherein each first clamping member further comprises a latching portion adjacent to the at least one stop member, each second clamping member further comprises a hook portion adjacent to the restricting portion, the hook portion hooks on the latching portion for restricting the push-button assembly from rotating relative to the main body along the second direction.

10. The electronic device as claimed in claim 9, wherein each hook portion is made of elastic material and comprises a distal end protruding from the frame, a main part spaced apart from the frame, and a hook disposed on one end of the main part which is away from the end portion.

11. The electronic device as claimed in claim 3, wherein the frame is annular shape, the push-button witch further comprises at least one elastic arm connecting the push-button with the frame, the at least one elastic arm comprises a first end portion connected to the push-button, a second end portion connected to the frame, and a body portion connecting the first end portion and the second end portion.

12. The electronic device as claimed in claim 11, wherein the body portion is arc shaped.

13. The electronic device as claimed in claim 5, wherein the frame is concaved to define at least one concavity, the standing portion moves to correspond to the at least one concavity for allowing the push-button assembly to move away from the main body along the third direction.

14. The electronic device as claimed in claim 5, wherein the frame comprises a first surface adjacent to the standing portion and parallel with the interior surface, the push-button assembly further comprises at least one first abutting rib arranged on the first surface for tightly engaging with the standing portion along the third direction.

15. The electronic device as claimed in claim 14, wherein the frame comprises a second surface opposite to the first surface, the push-button assembly further comprises at least one second abutting rib arranged on the second surface for decreasing the friction between the frame and the main body as the push-button assembly rotates.

16. A push-button assembly, comprising:
a push-button for being pushed;
a frame at least partly surrounding the push-button;
at least one elastic arm connecting to the push-button and the frame for allowing the push-button to move along a direction perpendicular to the frame when the push-button is pushed.

17. The push-button assembly as claimed in claim 16, wherein the frame comprises a first surface, the push-button assembly further comprises at least one first abutting rib disposed on the first surface for decreasing the space between the third surface and an object which extends above the first surface to partly covering the frame.

18. The push-button assembly as claimed in claim 17, wherein the frame comprises a second surface opposite to the first surface, the push-button assembly further comprises at least one second abutting rib disposed on the second surface for decreasing the friction between the fourth surface and an object which contacts the frame and move relative to the frame.

19. The push-button assembly as claimed in claim 18, wherein the frame is annular shaped and comprise a third surface connecting the first surface and the second surface and facing towards the push-button, the at least one elastic arm comprises a first end portion connected to the push-button, a second end portion connected to the third surface, and a body portion connecting the first distal end and the second distal end, the body portion is substantially parallel with the third surface.

20. The push-button assembly as claimed in claim 19, wherein the frame comprises a fourth surface opposite to the third surface, the fourth surface is depressed to form at least one concavity.
